(19) United States
(12) Patent Application Publication
(10) Pub. No.: US 2026/0190627 A1
(43) Pub. Date: Jul. 2, 2026

(54) DISPLAY DEVICE

(71) Applicant: Japan Display Inc., Tokyo (JP)

(72) Inventor: Tatsuya ISHII, Tokyo (JP)

(21) Appl. No.: 19/414,678

(22) Filed: Dec. 10, 2025

(30) Foreign Application Priority Data
Dec. 26, 2024 (JP) 2024-231334

(51) Int. Cl. H10K 59/121; H10K 59/131

(52) U.S. Cl. CPC H10K 59/1213; H10K 59/131

(57) ABSTRACT

A display device includes a plurality of pixels arranged in a matrix in a first direction and a second direction intersecting the first direction, and a plurality of individual semiconductor layers arranged along the first direction for each of the plurality of pixels. Each of the plurality of pixels includes a first region, a second region adjacent to the first region, a third region adjacent to the second region, and a fourth region adjacent to the third region. The first region, the second region, the third region, and the fourth region are arranged along the first direction. At least one semiconductor layer of the plurality of individual semiconductor layers is arranged in the second region, and at least one other semiconductor layer of the plurality of individual semiconductor layers is arranged in the fourth region.

### CROSS-REFERENCE TO RELATED APPLICATIONS

This application claims the benefit of priority to Japanese Patent Application No. 2024-231334 filed on Dec. 26, 2024, the entire contents of which are incorporated herein by reference.

### FIELD

An embodiment of the present invention relates to a display device.

### BACKGROUND

In recent years, a display device including a light-emitting element has been mounted on a television, a smartphone, or the like, and is becoming popular. For example, the display device includes a plurality of pixels and a control circuit for driving the plurality of pixels. Each of the plurality of pixels includes a plurality of transistors, a capacitive element, and a light-emitting element. The light-emitting element is an element that emits light in a self-luminous manner (a self-luminous light-emitting element), and is, for example, a light-emitting diode (Light Emitting Diode: LED), a minute light-emitting diode (micro LED), or an organic electroluminescence (Electro Luminescence: EL) element. The control circuit in the display device can supply a potential to each of the plurality of pixels and allow a current corresponding to the supplied potential to flow to the light emitting elements included in each of the plurality of pixels. Each of the light-emitting elements emits light with a luminance corresponding to a current flowing through the light-emitting element, and a pixel including the light-emitting element can display an image with a gradation corresponding to the luminance.

For example, a display device including a light-emitting element is known. For example, the pixels in the display device include nine transistors (a first transistor to a ninth transistor), two capacitive elements (a first capacitive element and a second capacitive element) connected in series, and one light-emitting element (LED). Further, for example, a driving method of the display device includes electrically connecting a gate electrode (Gate) of the first transistor and a node on one electrode side of the first capacitive element by the third transistor in an initialization period (Initialization period) and a light emission period (Light emitting period).

### SUMMARY

A display device includes a plurality of pixels arranged in a matrix in a first direction and a second direction intersecting the first direction, and a plurality of individual semiconductor layers arranged along the first direction for each of the plurality of pixels. Each of the plurality of pixels includes a first region, a second region adjacent to the first region, a third region adjacent to the second region, and a fourth region adjacent to the third region. The first region, the second region, the third region, and the fourth region are arranged along the first direction. At least one semiconductor layer of the plurality of individual semiconductor layers is arranged in the second region, and at least one other semiconductor layer of the plurality of individual semiconductor layers is arranged in the fourth region.

### BRIEF DESCRIPTION OF DRAWINGS

FIG. 1 is a schematic diagram showing a configuration of a display device according to an embodiment of the present invention.

FIG. 2 is a schematic diagram showing an input signal to a pixel circuit according to an embodiment of the present invention.

FIG. 3 is a circuit diagram showing a configuration of a pixel circuit according to an embodiment of the present invention.

FIG. 4 is a plan view showing a layout of pixels according to an embodiment of the present invention.

FIG. 5 is a plan view showing a layout of pixels according to an embodiment of the present invention.

FIG. 6 is a plan view showing a layout of pixels according to an embodiment of the present invention.

FIG. 7 is a cross-sectional view taken along A1-A2 in the layout shown in FIG. 5 or FIG. 6.

FIG. 8 is a cross-sectional view taken along B1-B2 in the layout shown in FIG. 5 or FIG. 6.

FIG. 9 is a cross-sectional view taken along C1-C2 in the layout shown in FIG. 5 or FIG. 6.

FIG. 10 is a sequence diagram showing a method for manufacturing a display device according to an embodiment of the present invention.

FIG. 11 is a sequence diagram showing a method for manufacturing a display device according to an embodiment of the present invention.

FIG. 12 is a plan view showing a layout of pixels according to an embodiment of the present invention.

FIG. 13 is a plan view showing a layout of pixels according to an embodiment of the present invention.

FIG. 14 is a plan view showing a layout of pixels according to an embodiment of the present invention.

FIG. 15 is a plan view showing a layout of a modified example of a pixel according to an embodiment of the present invention.

FIG. 16 is a plan view showing part of a layout of a modified example of a pixel according to an embodiment of the present invention.

### DESCRIPTION OF EMBODIMENTS

Hereinafter, embodiments of the present invention will be described with reference to the drawings and the like. However, the present invention can be implemented in many different aspects, and should not be construed as being limited to the description of the embodiments exemplified below. Further, in order to make the description clearer, the drawings may be schematically represented with respect to the width, thickness, shape, configuration, and the like of each part as compared with the actual embodiment, but the drawings are merely examples, and do not limit the interpretation of the present invention. In addition, the terms “first” and “second” for each element are convenient labels used to distinguish each element, and do not have any further meaning unless otherwise described.

Also, in the present specification, the expression “α includes A, B, or C,” “α includes any of A, B, or C,” “α includes one selected from the group consisting of A, B, and C,” and the like does not exclude cases where α includes a plurality of combinations of A to C unless otherwise specified. Furthermore, these expressions do not exclude the case where α includes other elements.

In one embodiment, a first direction D1 intersects a second direction D2 and a third direction D3 intersects the first direction D1 and the second direction D2 (plane D1D2).

In the present specification, when the terms “same” and “identical” are used, the same and identical may include errors within the scope of the design. In addition, in one embodiment of the present invention, when an error in the range of design is included, the expression “substantially the same” and “substantially identical” may be used in some cases.

An LED, a micro LED, an EL device, or the like can be used as a self-luminous light-emitting device in one embodiment of the present disclosure. In addition, the light-emitting device of the self-luminous type is not limited to the LED, the micro LED, or the EL device. In the display device according to one embodiment of the present invention, a self-luminous light-emitting element that does not deviate from the display device according to one embodiment of the present invention can be appropriately selected according to the application and specifications of the display device. The display device according to the embodiments described below is a display device using the EL device as the self-luminous light-emitting device. For example, the display device using the EL devices may be referred to as a self-luminous display device, an EL display device, or the like.

### 1. First Embodiment

### [1-1. Overview of Display Device 10]

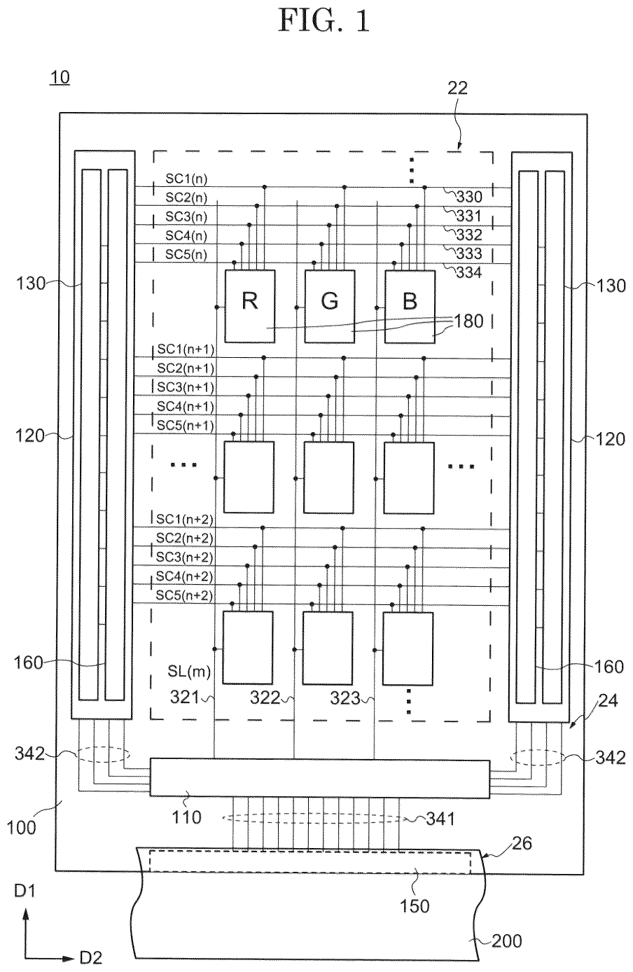

An outline of a display device 10 according to the first embodiment will be described with reference to FIG. 1. FIG. 1 is a schematic diagram showing a configuration of the display device 10. The configuration of the display device 10 shown in FIG. 1 is an example, and the configuration of the display device 10 is not limited to the configuration shown in FIG. 1.

The display device 10 includes an array board 100, a flexible printed circuit board 200 (FPC 200), and an IC chip 110. The display device 10 includes a display region 22 that overlaps the array substrate 100, a peripheral region 24 that surrounds the display region 22, and a terminal region 26.

In the display region 22, a plurality of pixels 180 is arranged in a matrix along the first direction D1 (column direction) and the second direction D2 (row direction) intersecting the first direction D1. The pixel 180 is the smallest unit constituting part of the image to be displayed in the display region 22. Each of the plurality of pixels 180 may correspond to, for example, a sub-pixel R, a sub-pixel G, and a sub-pixel B. One pixel may be formed by three sub-pixels. An arrangement of the plurality of pixels 180 is not limited, and the arrangement of the plurality of pixels 180 may be a delta arrangement, a pentile arrangement, or the like. For example, the arrangement of the plurality of pixels 180 of the display device 10 is a stripe arrangement.

The sub-pixel R, the sub-pixel G, and the sub-pixel B are configured to display images of different colors. For example, each of the sub-pixel R, the sub-pixel G, and the sub-pixel B includes a light-emitting element including a light-emitting layer that emits red, green, and blue. An arbitrary potential or current is supplied to each of the three sub-pixels, and the display device 10 can display an image.

For example, the IC chip 110 and two control circuits 120 are arranged in the peripheral area 24. The two control circuits 120 are arranged on the left and right sides of the display region 22. The IC chip 110 is connected to the terminal portion 150 using a connection wiring 341. Each of the two control circuits 120 is connected to the IC chip 110 using a connection wiring 342. The peripheral region 24 may be referred to as a frame region. The connection wiring 341 may be referred to as the connection wiring 341 alone, and a bundle of a plurality of connection wirings 341 may be referred to as a connection wiring 341. Similar to the connection wiring 341, the connection wiring 342 may be referred to as the connection wiring 342 alone, and a bundle of a plurality of connection wirings 342 may be referred to as the connection wiring 342.

The terminal region 26 is arranged with the terminal portion 150 and the FPC 200 electrically connected to the terminal portion 150. The terminal region 26 is a region opposed to a region where the display region 22 is arranged with respect to the peripheral region 24 along the first direction D1.

The FPC 200 is connected to an external device (not shown) outside the display device 10. The display device 10 is connected to an external device via the FPC 200 and the terminal portion 150. A control signal and a potential are transmitted from the external device to the display device 10 via the FPC 200 and the terminal portion 150. The display device 10 drives each pixel 180 arranged in the display device 10 by using the received control signal and potential from the external device. As a result, the display device 10 can display an image in the display region 22.

The IC chip 110 supplies signals, potentials, and the like for driving the respective pixels 180 to the two control circuits 120 and the respective pixels 180 (pixel circuits 181) via the FPC 200, the terminal portion 150, and the connection wiring 341.

Each of the IC chip 110 and the two control circuits 120 may be referred to as a control circuit alone, and a circuit group including part or all of each of the IC chip 110 and the two control circuits 120 may be referred to as a control circuit.

### [1-2. Configuration of IC Chip 110]

Referring to FIG. 1, an outline of the IC chip 110 will be described. The IC chip 110 is provided at a position adjoining the display area 22 along the first direction D1. Image data signal lines 321, 322, and 323 extend from the IC chip 110 in the first direction D1 and are connected to the plurality of pixels 180 arranged in the first direction D1.

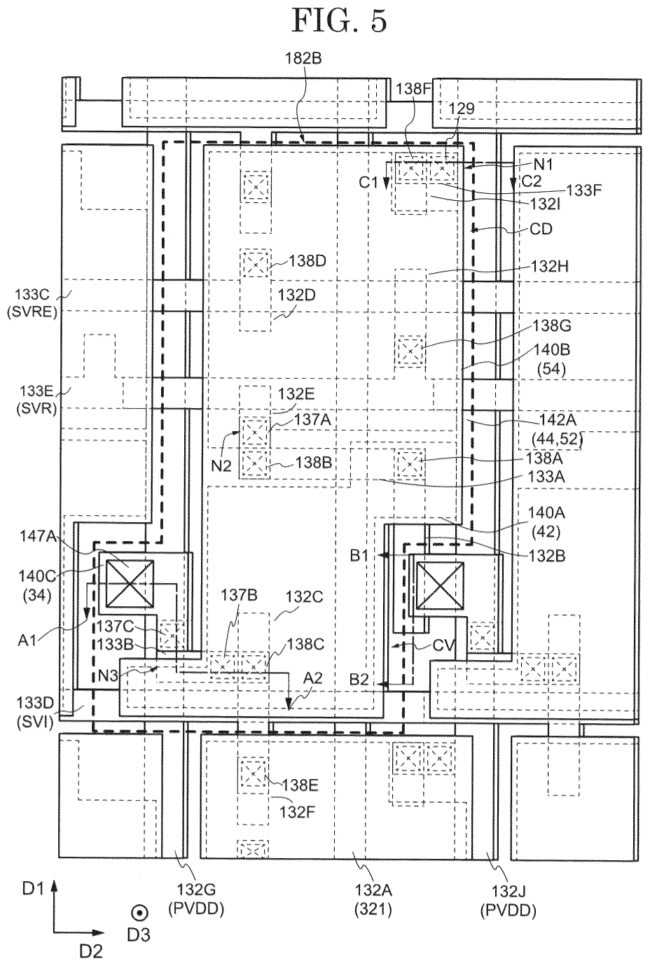

For example, the IC chip 110 includes a plurality of selection circuits (not shown). For example, each of the plurality of selection circuits is a switch controlled based on an on signal and an off signal supplied to a selection signal. The selection circuit is selected by the on signal supplied to the selection signal and supplies an image data signal SL(m) including a data signal VDATA to the image data signal line 321 and the pixel 180 electrically connected to the image data signal line 321. For example, the selection signal and the image data signal SL(m) are transmitted by a digital signal from the external device to the IC chip 110 via the FPC 200 and the terminal portion 150. Further, for example, the data signal VDATA (the image data signal SL(m)) is DA (digital-analog) converted by the IC chip 110 into an analog signal including a data potential equal to or higher than a potential VSIGL (see FIG. 5) and equal to or lower than a potential VSIGH (see FIG. 5). The potential VSIGH is a potential higher than the potential VSIGL.

For example, the on signal is a signal including a potential that conducts the selection circuit (switch), and the off signal is a signal including a potential that blocks the selection circuit (switch). In the present disclosure, the on signal may be a high level potential (high, High, HI), the off signal may be a low level potential (low, Low, LO), the on signal may be a low level potential (low, Low, LO), and the off signal may be a high level potential (high, High, HI). The high level potential is higher than the low level potential. In the display device according to an embodiment of the present specification, as an example, the on signal is a high-level potential and the off signal is a low-level potential.

### [1-3. Configuration of Control Circuit 120]

An outline of the control circuit 120 will be described with reference to FIG. 1. The two control circuits 120 are arranged at positions adjoining both sides of the display region 22 along the second direction D2. A scan signal line 330, a scan signal line 331, a scan signal line 332, a scan signal line 333, and a scan signal line 334 extend from the control circuit 120 in the second direction D2 and are connected to the plurality of pixels 180 arranged in the second direction D2. For example, each scan signal line of the display device 10 shown in FIG. 1 is connected to both of the two control circuits 120. Each scan signal line may be connected to one control circuit 120 of the two control circuits 120. For example, an n-th scan signal line may be electrically connected to the control circuit 120 on a right side of the display region 22 along the second direction D2, and an n+1-th scan signal line may be electrically connected to the control circuit 120 on a left side of the display region 22 along the second direction D2. The number n is a positive integer.

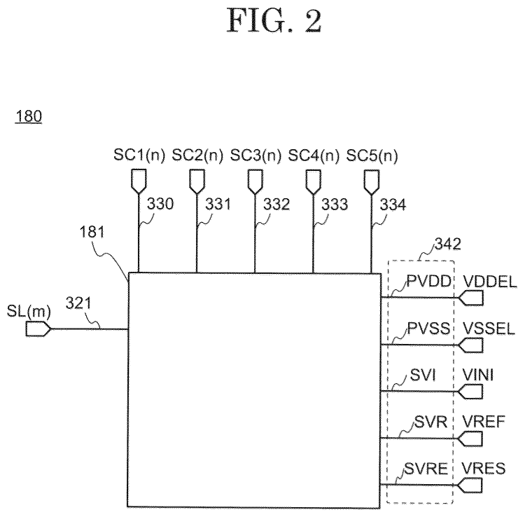

The control circuit 120 includes a shift register circuit 130 and a scan driver circuit 160. For example, the control circuit 120 is a gate driver, and receives a control signal including a clock signal, a start pulse, a plurality of enable signals, and the like, and potentials such as a driving potential VDDEL (see FIG. 2) and a standard potential VSSEL (see FIG. 2). The control circuit 120 can sequentially select scanning lines according to an input of the control signal and power supply.

The shift register circuit 130 is electrically connected to the scan driver circuit 160. The shift register circuit 130 includes a plurality of shift registers (not shown). Further, the plurality of control signals described above is supplied to the shift register circuit 130 via the plurality of connection wirings 342, the driving potential VDDEL is supplied via a driving potential line PVDD (see FIG. 2), and the standard potential VSSEL is supplied via a standard potential line PVSS (see FIG. 2). The shift register circuit 130 has a role of generating a plurality of output signals (not shown) shifted at different timings based on the plurality of control signals described above, and sequentially outputting the output signals to the scan driver circuit 160.

The scan driver circuit 160 includes a plurality of scan drivers (not shown). For example, the plurality of scan drivers is supplied with the plurality of output signals from the shift register circuit 130, the plurality of enable signals described above is supplied from the IC chip 110 via the plurality of connection wirings 342, the driving potential VDDEL is supplied via the driving potential line PVDD, and the standard potential VSSEL is supplied via the standard potential line PVSS. The plurality of scan drivers is configured to sequentially supply scan signals having different timings (for example, a first scan signal SC1(n), a second scan signal SC2(n), a third scan signal SC3(n), a fourth scan signal SC4(n), and a fifth scan signal SC5(n)) to the respective scan signal lines based on the plurality of output signals and the plurality of enable signals (not shown), and to drive pixels 180 (pixel circuits 181) electrically connected to the respective scan signal lines. For example, the third scan signal SC3(n) and the scan signal line 332 to which the third scan signal SC3(n) is supplied is a so-called scan signal and scan signal line.

### [1-4. Configuration of Pixel 180]

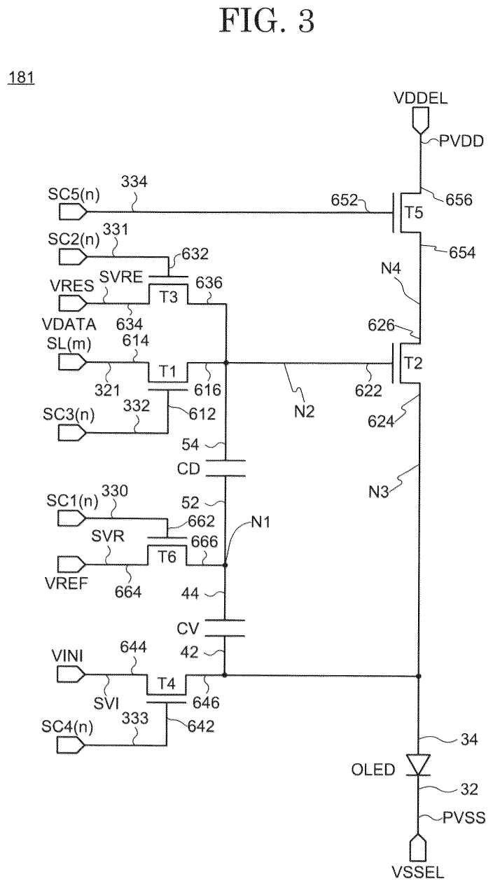

Referring to FIG. 1 to FIG. 3, an outline of the pixel 180 and the pixel circuit 181 will be described. FIG. 2 is a schematic diagram showing an input signal to the pixel circuit 181 included in the pixel 180. FIG. 3 is a circuit diagram showing a configuration of the pixel circuit 181. As an example, FIG. 2 and FIG. 3 show the configuration of the pixel circuit 181 of the pixel 180 shown in FIG. 1. The configurations of the pixel 180 and the pixel circuit 181 are not limited to the configuration shown in FIG. 1 to FIG. 3. Configurations that are the same as or similar to those in FIG. 1 are described as necessary, and descriptions of the same or similar configurations as those in FIG. 1 may be omitted.

The pixel circuit 181 is a circuit for driving the pixel 180. Pixel circuits of the sub-pixel R, the sub-pixel G, and the sub-pixel B included in the pixel 180 are the same as those of the pixel circuit 181, and differ in the colors emitted by the light-emitting device OLED.

As shown in FIG. 2, the pixel circuit 181 is supplied with the image data signal SL(m), the first scan signal SC1(n), the second scan signal SC2(n), the third scan signal SC3(n), the fourth scan signal SC4(n), the fifth scan signal SC5(n), a reset potential VRES, a reference potential VREF, and an initialization potential VINI. Further, as a power source for driving the pixel 180, the driving potential VDDEL and the standard potential VSSEL are supplied to the pixel circuit 181. For example, the reset potential VRES, the reference potential VREF, the initialization potential VINI, the driving potential VDDEL, and the standard potential VSSEL may be constant potentials, and may be variable potentials that vary depending on the timings of the respective signals.

The first scan signal SC1(n) is supplied to the scan signal line 330, the second scan signal SC2(n) is supplied to the scan signal line 331, the third scan signal SC3(n) is supplied to the scan signal line 332, the fourth scan signal SC4(n) is supplied to the scan signal line 333, and the fifth scan signal SC5(n) is supplied to the scan signal line 334.

Further, the reset potential VRES is supplied to a reset potential line SVRE, the reference potential VREF is supplied to a reference potential line SVR, the initialization potential VINI is supplied to an initialization potential line SVI, the driving potential VDDEL is supplied to the driving potential line PVDD, and the standard potential VSSEL is supplied to the reference potential line SVR. For example, the reset potential line SVRE, the reference potential line SVR, the initialization potential line SVI, the driving potential line PVDD, and the standard potential line PVSS are electrically connected to the different connection wirings 342. Further, for example, each of the reset potential line SVRE, the reference potential line SVR, the initialization potential line SVI, the driving potential line PVDD, and the standard potential line PVSS may be different connection wirings 342.

For example, the reset potential VRES, the reference potential VREF, the initialization potential VINI, the driving potential VDDEL, and the standard potential VSSEL may be supplied from the external device to the IC chip 110 via the FPC 200, the terminal portion 150, and the connection wiring 341. Further, for example, the reset potential VRES, the reference potential VREF, the initialization potential VINI, the driving potential VDDEL, and the standard potential VSSEL may be generated by the IC chip 110, and may be supplied to the plurality of pixels 180 (the pixel circuit 181) via the connection wiring 342, the reset potential line SVRE, the reference potential line SVR, the initialization potential line SVI, the driving potential line PVDD, and the standard potential line PVSS from the IC chip 110. In addition, although not shown, the reset potential VRES, the reference potential VREF, the initialization potential VINI, the driving potential VDDEL and the standard potential VSSEL can be connected to the reset potential line SVRE, the reference potential line SVR, the initialization potential line SVI, the driving potential line PVDD, and the standard potential line PVSS via the FPC 200, the terminal portion 150, and the connection wiring 341, without passing through the IC chip 110 and the connection wiring 342 from the external device, and may be supplied to the plurality of pixels 180 (pixel circuit 181). For example, the reset potential VRES, the reference potential VREF, the initialization potential VINI, and the standard potential VSSEL are lower than the driving potential VDDEL.

As shown in FIG. 3, the pixel 180 (pixel circuit 181) includes a first transistor T1, a second transistor T2, a third transistor T3, a fourth transistor T4, a fifth transistor T5, a sixth transistor T6, a capacitive element CV, a capacitive element CD, and a light-emitting device OLED. Each of these transistors includes a gate electrode and a pair of electrodes (a source electrode and a drain electrode) including a first electrode and a second electrode. Each of the capacitive element CV, the capacitive element CD, and the light-emitting device OLED has a pair of electrodes including a first electrode and a second electrode. In addition, the capacitive element CV may be referred to as a first capacitive element, and the capacitive element CD may be referred to as a second capacitive element.

For example, the first transistor T1 is a selection transistor. The first transistor T1 has a function of supplying the image data signal SL(m) to a second node N2.

For example, the second transistor T2 is a driving transistor. As will be described later, a threshold voltage (a potential difference Vgs that becomes a threshold value) VTH is acquired between a first node N1 and a first electrode (source) 624 based on the reset potential VRES, and the acquired threshold voltage VTH is applied to the capacitive element CV, whereby the threshold voltage VTH is acquired and held (stored). Further, the second transistor T2 controls an amount of current flowing from the driving potential line PVDD to the light-emitting device OLED based on the gate potential (potential between a gate electrode 622 and the first electrode 624) and the input image data signal SL(m) in which the variation in the threshold-voltage VTH is corrected. That is, the second transistor T2 has a function of causing the light-emitting device OLED to emit light by causing a current corresponding to a display gradation (luminance) to flow from the driving potential VDDEL to the light-emitting device OLED in the light-emitting device OLED.

For example, the third transistor T3 has functions of conducting the second node N2 and the reset potential line SVRE, supplying the reset potential VRES to the second node N2, and fixing the potential supplied to the second node N2 to the reset potential VRES. As will be described later, when the potential supplied to the second node N2 is fixed to the reset potential VRES, a current flows from the driving potential line PVDD to the fourth node N4 and the third node N3 via the fifth transistor T5, and the capacitive element CV (a first electrode 42 of the capacitive element CV) is charged, and when the potential difference Vgs (the potential difference Vgs between a potential supplied to the gate electrode 622 (second node N2) and a potential supplied to the first electrode 624 (third node N3)) reaches the threshold voltage VTH, the charging is stopped.

The fourth transistor T4 has a function of conducting the third node N3 and the initialization potential line SVI, supplying the initialization potential VINI to the third node N3, and initializing the third node N3.

The fifth transistor T5 has a function of making the driving potential line PVDD and the fourth node N4 conductive.

The sixth transistor T6 has functions of conducting the first node N1 and the reference potential line SVR, supplying the reference potential VRED to the first node N1, and fixing the potential supplied to the first node N1 to the reference potential VREF at the time of initialization of the third node N3, at the time of acquiring and holding the threshold voltage VTH, and at the time of writing the image data signal SL(m).

The capacitive element CV has a function of holding (storing) charges corresponding to the threshold voltage VTH of the second transistor T2. That is, the capacitive element CV has a function of holding (storing) a potential difference between a potential supplied to the first node N1 and a potential supplied to the third node N3, including information on the threshold voltage VTH of the second transistor T2. A method for driving the display device 10 includes obtaining the threshold voltage VTH by applying the driving potential VDDEL from a second electrode 626 (drain electrode) of the second transistor T2 via the driving potential line PVDD.

The capacitive element CD has a function of holding (storing) charges corresponding to data potentials (potentials equal to or higher than the potential VSIGL (see FIG. 5) and equal to or lower than the potential VSIGH (see FIG. 5)) included in the image data signal SL(m) supplied to the second node N2. That is, the capacitive element CD has a function of holding (storing) a potential difference between a potential supplied to the second node N2 and a potential supplied to the first node N1, including data potential information of the image data signal SL(m).

The light-emitting device OLED has a diode characteristic and has a function of emitting light based on a current flowing through the light-emitting device OLED. The current flowing through the light-emitting device OLED is a drain current (current Ion) of the second transistor T2.

The first transistor T1 includes a gate electrode 612, a first electrode 614, and a second electrode 616. The gate electrode 612 is electrically connected to the scan signal line 332. The first electrode 614 is electrically connected to the image data signal line 321. The second electrode 616 is electrically connected to the second node N2, the gate electrode 622 of the second transistor T2, a second electrode 636 of the third transistor T3, and a second electrode 54 of the capacitive element CD. The first transistor T1 is switched using the third scan signal SC3(n). In other words, in the first transistor T1, a conduction state (on state) and a non-conduction state (off state) are controlled by the third scan signal SC3(n). In the case where the signal supplied to the third scan signal SC3(n) is LO, the first transistor T1 becomes non-conductive. In the case where the signal supplied to the third scan signal SC3(n) is HI, the first transistor T1 becomes conductive.

The second transistor T2 includes the gate electrode 622, the first electrode 624, and the second electrode 626. The first electrode 624 is electrically connected to the third node N3, the first electrode 42 of the capacitive element CV, and a second electrode 34 of the light-emitting device OLED. The second electrode 626 is electrically connected to the fourth node N4 and a first electrode 654 of the fifth transistor T5. The threshold voltage of the second transistor T2 is the threshold voltage VTH. The second transistor T2 controls the current flowing through the light-emitting device OLED in accordance with the potential difference Vgs and a potential difference Vds between a potential supplied to the second electrode 626 (the fourth node N4) and the potential supplied to the first electrode 624 (the third node N3). For example, if the potential difference Vgs is smaller than the threshold voltage VTH, the second transistor T2 becomes non-conductive. In this case, since no current flows through the light-emitting device OLED, the pixel 180 displays black. For example, if the potential difference Vgs is equal to or higher than the threshold voltage VTH and the potential difference Vds is larger than 0 V, the second transistor T2 becomes conductive, and the current flowing through the light-emitting device OLED is controlled according to the magnitude based on the gradation of the display of the potential difference Vgs, and the light-emitting device OLED emits light with the luminance based on the gradation of the display.

The third transistor T3 includes a gate electrode 632, a first electrode 634, and the second electrode 636. The gate electrode 632 is electrically connected to the scan signal line 331. The first electrode 634 is electrically connected to the reset potential line SVRE. The third transistor T3 is switched using the second scan signal SC2(n). In other words, in the third transistor T3, the conduction state (on state) and the non-conduction state (off state) are controlled by the second scan signal SC2(n). If the signal supplied to the second scan signal SC2(n) is LO, the third transistor T3 becomes non-conductive, and if the signal supplied to the second scan signal SC2(n) is HI, the third transistor T3 becomes conductive.

The fourth transistor T4 includes a gate electrode 642, a first electrode 644, and a second electrode 646. The gate electrode 642 is electrically connected to the scan signal line 333. The first electrode 644 is electrically connected to the initialization potential line SVI. The fourth transistor T4 is switched using the fourth scan signal SC4(n). In other words, in the fourth transistor T4, the conduction state (on state) and the non-conduction state (off state) are controlled by the fourth scan signal SC4(n). If the signal supplied to the fourth scan signal SC4(n) is LO, the fourth transistor T4 becomes non-conductive, and if the signal supplied to the fourth scan signal SC4(n) is HI, the fourth transistor T4 becomes conductive.

The fifth transistor T5 includes a gate electrode 652, the first electrode 654, and a second electrode 656. The gate electrode 652 is electrically connected to the scan signal line 334. The second electrode 656 is electrically connected to the driving potential line PVDD. The fifth transistor T5 is switched using the fifth scan signal SC5(n). In other words, in the fifth transistor T5, the conduction state (ON state) and the non-conduction state (OFF state) are controlled by the fifth scan signal SC5(n). If the signal supplied to the fifth scan signal SC5(n) is LO, the fifth transistor T5 becomes non-conductive, and if the signal supplied to the fifth scan signal SC5(n) is HI, the fifth transistor T5 becomes conductive.

The sixth transistor T6 includes a gate electrode 662, a first electrode 664, and a second electrode 666. The gate electrode 662 is electrically connected to the scan signal line 330. The first electrode 664 is electrically connected to the reference-potential line SVR. The second electrode 666 is electrically connected to the first node N1, a second electrode 44 of the capacitive element CV, and a first electrode 52 of the capacitive element CD. The sixth transistor T6 is switched using the first scan signal SC1(n). In other words, in the sixth transistor T6, the conduction state (on state) and the non-conduction state (off state) are controlled by the first scan signal SC1(n). If the signal supplied to the first scan signal SC1(n) is LO, the sixth transistor T6 becomes non-conductive, and if the signal supplied to the first scan signal SC1(n) is HI, the sixth transistor T6 becomes conductive.

The capacitive element CV includes the first electrode 42 and the second electrode 44.

The capacitive element CD includes the first electrode 52 and the second electrode 54.

A first electrode 32 of the light-emitting device OLED is a cathode, and the second electrode 34 of the light-emitting device OLED is an anode. The first electrode 32 is electrically connected to the standard potential line PVSS.

For example, it is assumed that the conductive state of the transistor in the display device 10 indicates a state in which the source electrode and the drain electrode of the transistor are conductive and the transistor is on (ON), and the non-conductive state of the transistor in the display device 10 indicates a state in which the source electrode and the drain electrode of the transistor are non-conductive and the transistor is off (OFF). In addition, in each transistor, the source electrode and the drain electrode may be interchanged depending on the potential or potential supplied to each electrode. In addition, even if the transistor is in the off state, it can be easily understood by a person skilled in the art that a slight current flows, such as a leakage current.

Each transistor shown in FIG. 3 is an n-channel field effect transistor. Each transistor includes a channel region. For example, the channel region is a region through which a current flows between a first electrode (which may be referred to as a drain or drain electrode, for example) and a second electrode (which may be referred to as a source or source electrode, for example) of each transistor. As will be described in detail later, for example, the channel region includes a Group 14 element such as silicon or germanium, or an oxide exhibiting semiconductor characteristics. Further, for example, the transistors in the display device 10 are formed using thin film transistors (TFT). The display device 10 may appropriately adapt the configuration of the transistor, the connection of the storage capacitor, the power supply potential, and the like according to the application and specifications.

### [1-5. Structure of Pixel 180]

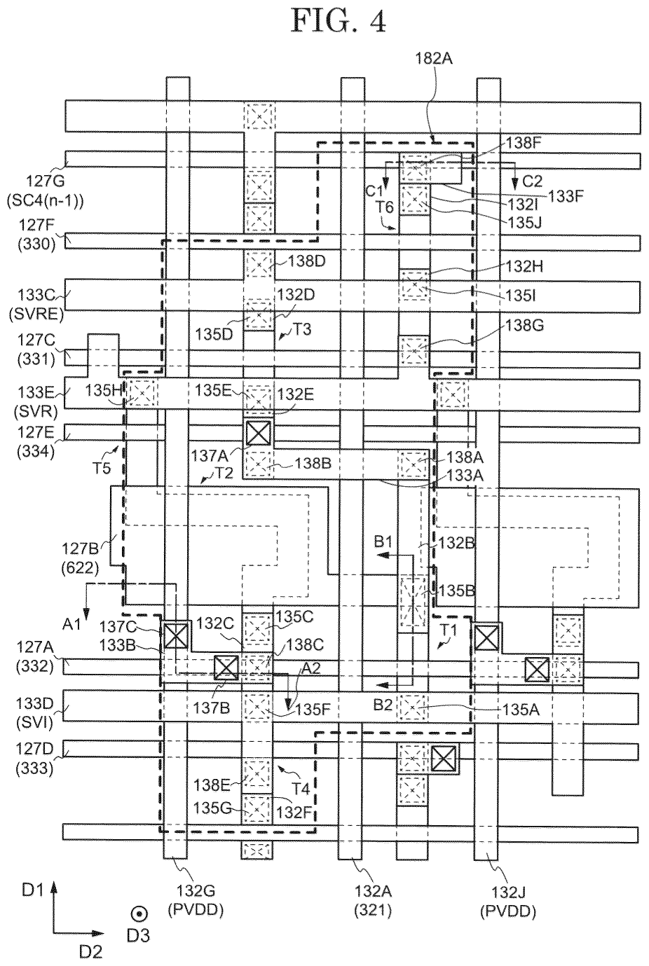

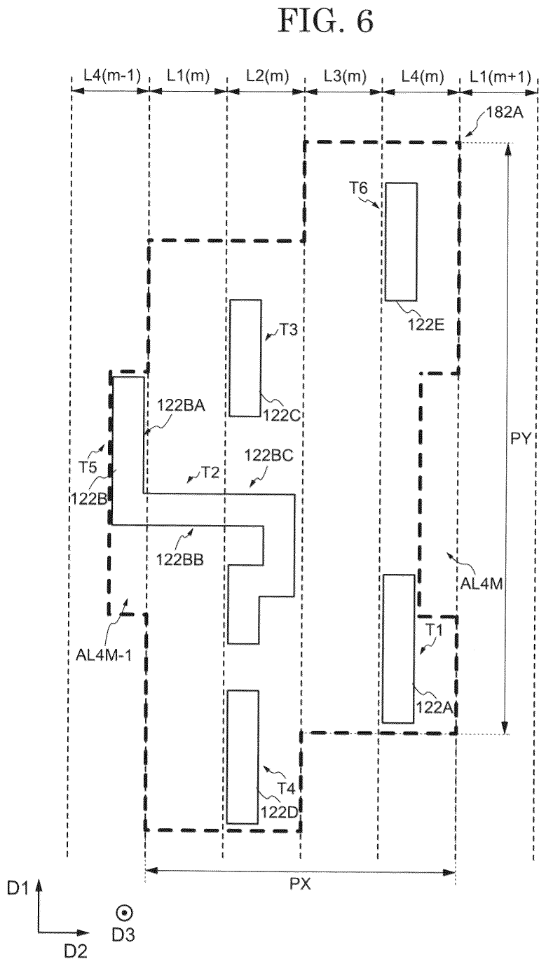

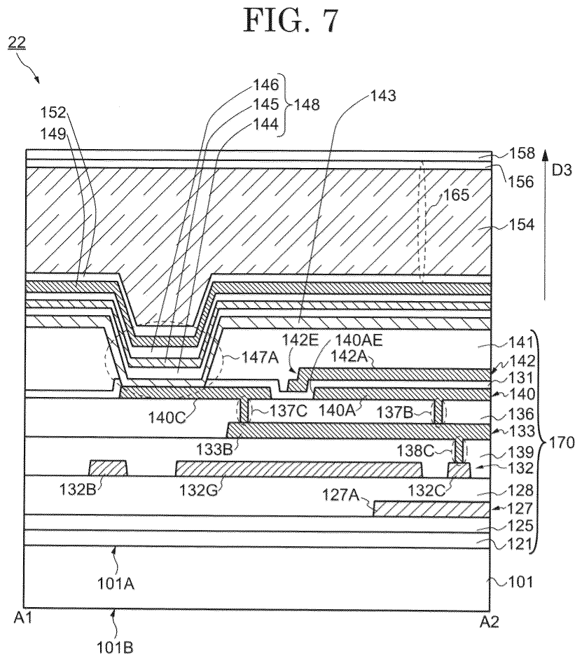

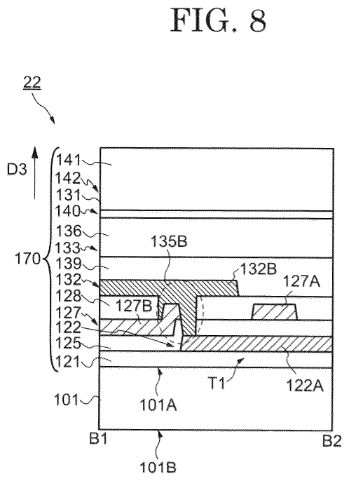

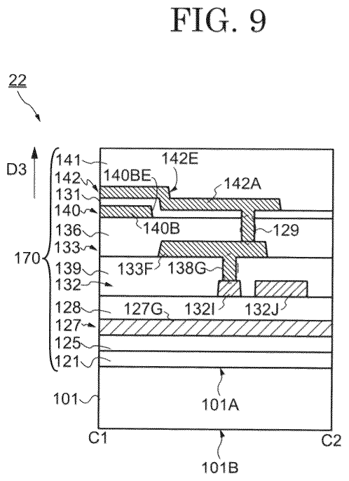

The structure of the pixel 180 will be described with reference to FIG. 4 to FIG. 14. FIG. 4 to FIG. 6 are diagrams showing the pixels 180 when the display device 10 is viewed from a front side (a first surface 101A). FIG. 6 is a plan view of a semiconductor layer 122 shown in FIG. 4. FIG. 7 is a cross-sectional view taken along A1-A2 in the layout shown in FIG. 4 or FIG. 5. FIG. 8 is a cross-sectional view taken along B1-B2 in the layout shown in FIG. 4 or FIG. 5. FIG. 9 is a cross-sectional view taken along C1-C2 in the layout shown in FIG. 4 or FIG. 5. The layouts of the pixels 180 shown in FIG. 4 to FIG. 6 and the cross sections of the pixels 180 shown in FIG. 7 to FIG. 9 are examples, and the layout and the cross section of the pixels 180 are not limited to the examples shown in FIG. 4 to FIG. 9. Configurations that are the same as or similar to those in FIG. 1 to FIG. 3 will be described as necessary.

First, a configuration of the pixel 180 in a plan view will be described.

The layout diagram of the pixel 180 shown in FIG. 4 includes the semiconductor layer 122, a conductive layer 127, a conductive layer 132, a first contact hole opening 135, a conductive layer 133, a second contact hole opening 138, and a third contact hole opening 137, and the semiconductor layer 122, the conductive layer 127, the conductive layer 132, the first contact hole opening 135, the conductive layer 133, the second contact hole opening 138, and the third contact hole opening 137 are omitted in order to make the drawing easy to see. In the layout diagram of the pixel 180 shown in FIG. 4, a configuration of an upper layer over an insulating layer 141 is omitted along the third direction D3. A region in which the pixels 180 are laid out in a layer below the insulating layer 141 is inside a region 182A indicated by a thick broken line.

In addition, in the layout of the pixel 180 shown in FIG. 5, in order to make the drawings easier to view, the elements shown in FIG. 4 (parts of the semiconductor layer 122, the conductive layer 127, the conductive layer 132, the first contact hole opening 135, and the conductive layer 133) are omitted, the remaining elements shown in FIG. 4, a portion of a conductive layer 140 and a fourth contact hole opening 129 are shown as dashed lines, a portion of the conductive layer 132, the portion of the conductive layer 140, a conduction layer 142, a contact hole opening 147 for the anode shown in FIG. 4 are shown as solid lines, and each other element and a reference sign of each element are omitted. A region in which the pixels 180 are laid out in a layer above the insulating layer 141 is inside a region 182B indicated by a thick broken line.

As shown in FIG. 6, the pixel 180 includes a first region L1(m), a second region L2(m) provided adjacent to the first region L1(m), a third region L3(m) provided adjacent to the second region L2(m), and a fourth region L4(m) provided adjacent to the third region L3(m). Each of the first region L1(m), the second region L2(m), the third region L3(m) and the fourth region L4(m) is arranged along the first direction. For example, the pixel 180 is one of the plurality of pixels 180 arranged in an m-th column among the plurality of pixels 180 arranged in a matrix in the first direction D1 and the second direction D2. For example, one pixel of the plurality of pixels 180 arranged in the m-th column may be referred to as a first pixel or a second pixel. The number m is a positive integer.

The first region L1(m) includes the semiconductor layer 122BB along the second direction and does not include a semiconductor layer along the first direction. The second region L2(m) includes a semiconductor layer 122C, a semiconductor layer 122BC, and a semiconductor layer 122D along the first direction. The third region L3(m) does not include a semiconductor layer. The fourth region L4(m) includes semiconductor layers 122E and 122A along the first direction. A fourth region L4(m−1) includes a semiconductor layer 122BA along the first direction.

For example, the fourth region L4(m−1) is a region included in one pixel of the plurality of pixels 180 arranged in the m−1-th column among the plurality of pixels 180 arranged in the matrix in the first direction D1 and the second direction D2. For example, one pixel of the plurality of pixels 180 arranged in the first m−1 column may be referred to as a second pixel or a first pixel. Further, a first region L1(m+1) shown in FIG. 6 is a first region of one pixel of the plurality of pixels 180 arranged in the m+1-th column among the plurality of pixels 180 arranged in the matrix in the first direction D1 and the second direction D2. For example, one pixel among the plurality of pixels 180 arranged in the m+1-th column may be referred to as a third pixel. The second pixel is adjacent to the first pixel along the second direction D2, and the first pixel is adjacent to the third pixel along the second direction D2. That is, the first pixel is arranged adjacent between the second pixel and the third pixel.

Since the display device 10 includes the plurality of pixels 180 arranged in a matrix in the first direction D1 and the second direction D2, the region 182A is arranged in a matrix in the first direction D1 and the second direction D2, and is laid down. Similar to the region 182A, the region 182B is arranged and tiled in a matrix in the first direction D1 and the second direction D2.

Thus, a region AL4M-1 of a certain pixel is aligned with a fourth region L4(m−1) of the neighboring pixel along the second direction D2, and a region AL4M of a certain pixel is aligned with a fourth region L4(m) of the neighboring pixel. That is, the plurality of pixels 180 arranged in a matrix in the first direction D1 and the second direction D2 is aligned so as to compensate for the missing regions of the regions of the neighboring pixels along the second direction D2. In addition, although not shown, the pixels adjacent along the first direction D1 are also aligned so as to compensate for the missing regions of the regions of the adjacent pixels in the same manner as the pixels adjacent along the second direction D2. For example, a length (pitch) of the pixel 180 in the first direction D1 is a length PX, and a length (pitch) of the pixel 180 in the second direction D2 is a length PY.

The display device 10 limits the region in which the semiconductor layer is arranged along the first direction D1 to the second region L2(m) and the fourth region L4(m), and shifts a position of the region 182A along the third direction D3 and a position of the region 182B along the third direction D3, so that the plurality of pixels 180 can be closely arranged along the first direction D1 and the second direction D2. As a result, the display device 10 can have high definition.

Next, a configuration of the pixel 180 in a cross-sectional view will be described.

The cross section of the pixel 180 shown in FIG. 7 is a cross section along an anode 143, a functional layer 148, a cathode 149, a sealing film 165, a cover film 158, a contact hole opening 147A for the anode, a first wiring 132B, a first electrode 140C, a first wiring 132G, a second wiring 133B, a third contact hole opening 137C, an end portion 142E of the second electrode, a second electrode 142A, an end portion 140AE of the first electrode, a first electrode 140A, a gate wiring 127A, a third contact hole opening 137B, a second contact hole opening 138C, and a first wiring 132C as an example of the cross section of the pixel 180.

The cross section of the pixel 180 shown in FIG. 8 is a cross section along the first wiring 132B, a gate wiring 127B, a first contact hole opening 135B, the semiconductor layer 122A, and the gate wiring 127A, as an exemplary cross section of the pixel 180.

The cross section of the pixel 180 shown in FIG. 9 is, as an example of the cross section of the pixel 180, a cross section along the second electrode 142A, a first electrode 140B, a gate wiring 127G, an end portion 140BE of the first electrode, the end portion 142E of the second electrode, the gate wiring 127G, a second wiring 133F, a second contact hole opening 138G, a first wiring 132I, the fourth contact hole opening 129, and a first wiring 132J. In the cross section of the pixel 180 shown in FIG. 8 and FIG. 9, the configuration of the upper layer over the insulating layer 141 is omitted along the third direction D3.

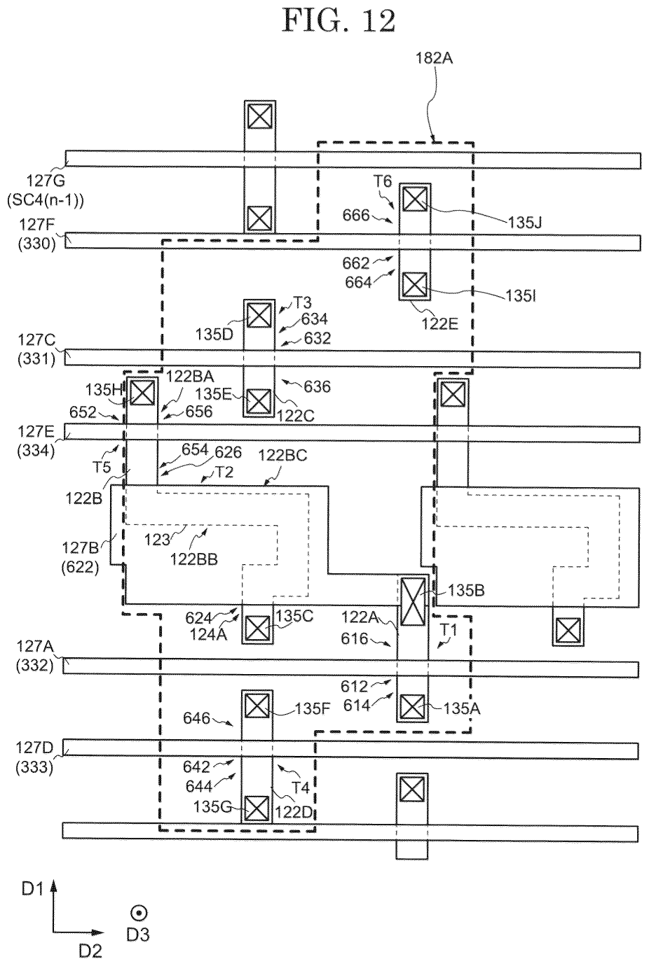

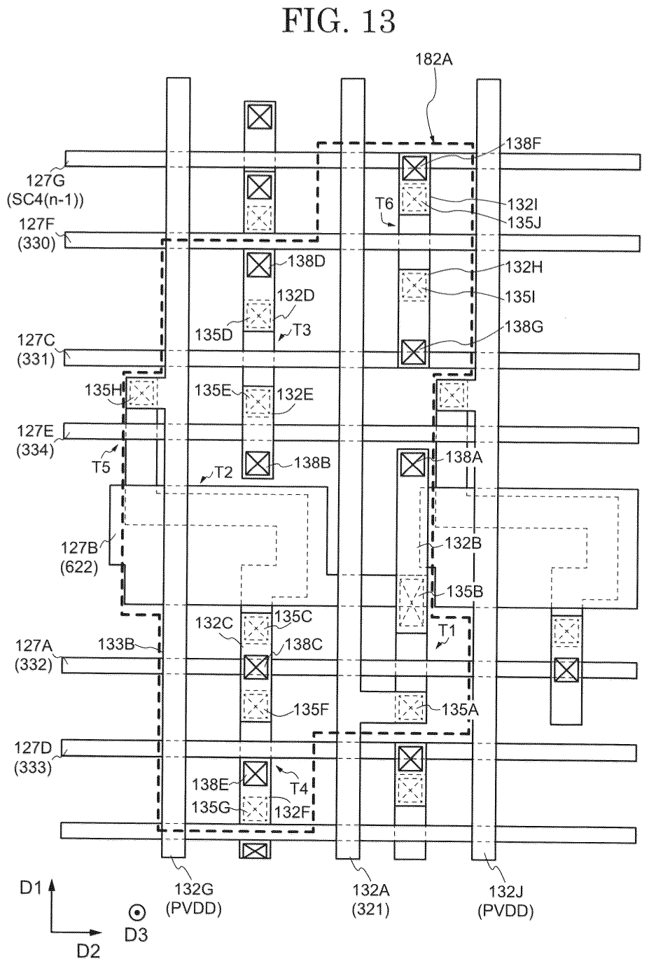

A substrate 101 includes a first surface 101A and a second surface 101B opposed to the first surface 101A. The semiconductor layer 122 is arranged on the first surface 101A of the substrate 101 via a base layer 121. The semiconductor layer 122 includes the semiconductor layer 122A, a semiconductor layer 122B, the semiconductor layer 122C, and the semiconductor layer 122D (see FIG. 6, FIG. 12, and FIG. 13). The semiconductor layer 122B includes a channel region 123 (see FIG. 6, FIG. 12, and FIG. 13) and an impurity region 124A (see FIG. 6, FIG. 12, and FIG. 13). For example, the impurity region is referred to as a source region or a drain region. Further, for example, the second transistor T2 includes the semiconductor layer 122B, and the first electrode 624 (see FIG. 12) and the second electrode 626 (see FIG. 12) include the impurity region 124A. In other words, the semiconductor layer 122B includes the channel region of the second transistor T2. Similar to the second transistor T2, the first transistor T1 includes the semiconductor layer 122A, and the first electrode 614 (see FIG. 12) and the second electrode 616 (see FIG. 12) include the impurity region. In other words, the semiconductor layer 122A includes the channel region of the first transistor T1.

On the semiconductor layer 122, a gate insulating layer 125, the conductive layer 127, an insulating layer 128, and the conductive layer 132 are arranged in this order. The conductive layer 127 includes the gate wiring 127A (the scan signal line 332 and the gate electrode 612, see FIG. 12 and FIG. 13), the gate wiring 127B (the gate electrode 622, see FIG. 12 and FIG. 13), and a signal line to which the gate wiring 127G (a signal line to which the scan signal line SC4(n−1) is supplied, see FIG. 12 and FIG. 13). The conductive layer 132 includes the first wiring 132B, the first wiring 132G, the first wiring 132C, the first wiring 132I, and the first wiring 132J. In addition, a region where the conductive layer 127 and the semiconductor layer 122 overlap each other is a channel region. In other words, a region where the gate electrode and the semiconductor layer of each transistor overlap each other is a channel region.

Each of the transistors of the pixel 180 is formed using the semiconductor layer 122 (for example, the semiconductor layer 122B, the channel region 123, and the impurity region 124A, see FIG. 12), the gate insulating layer 125, and the conductive layer 127 (for example, the gate wiring 127B, see FIG. 12 and FIG. 13).

A first contact hole opening 135B reaching the semiconductive layer 122 and the conductive layer 127 penetrates through the gate insulating layer 125 and the insulating layer 128, and is arranged in the gate insulating layer 125 and the insulating layer 128. For example, the first contact hole opening 135B exposes the semiconductor layer 122A (for example, the second electrode 616, see FIG. 12) and the gate wiring 127B, and the first wiring 132B is electrically connected to the semiconductor layer 122A and the gate wiring 127B by the first contact hole opening 135B. That is, the first contact hole opening may penetrate through the gate insulating layer 125 and the insulating layer 128 and may expose the semiconductor layer 122, and the first contact hole opening may penetrate through the insulating layer 128 and may expose the conductive layer 127.

An insulating layer 139 is arranged on the insulating layer 128 where the conductive layer 132 is not arranged, and is arranged so as to cover the conductive layer 132.

A second contact hole opening is arranged in the insulating layer 139. For example, the second contact hole opening includes the second contact hole openings 138C and 138G. The conductive layer 133 is arranged on the insulating layer 139 and in the second contact hole opening 138. The conductive layer 133 includes the second wiring 133B and the second wiring 133F. The second contact hole opening 138C penetrates the insulating layers 139 and exposes the first wiring 132C. The second wiring 133B is electrically connected to the first wiring 132C via the second contact hole opening 138C. Similar to the second contact hole opening 138C, the second contact hole opening 138G penetrates through the insulating layers 139 and exposes the first wiring 132I. The second wiring 133F is electrically connected to the first wiring 132I via the second contact hole opening 138G. Further, although not shown, for example, the second contact hole opening 138 exposes a part of a plurality of terminals (not shown) included in the terminal portion 150.

An insulating layer 136 is arranged on the insulating layer 139 where the conductive layer 133 is not arranged, and is arranged so as to cover the conductive layer 133.

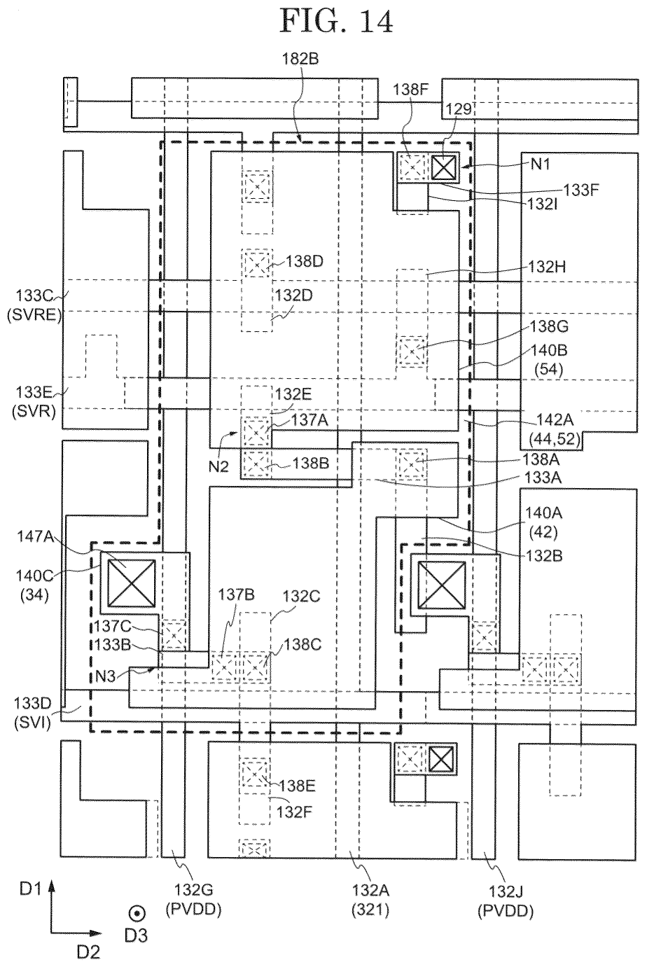

A third contact hole opening is arranged in the insulating layer 136. For example, the third contact hole opening 137 includes the third contact hole openings 137B and 137C. The conductive layer 140 is arranged over the insulating layer 136 and in the third contact hole opening 137. The conductive layer 140 includes the first electrode 140C (see second electrode 34, FIG. 5 and FIG. 14), the first electrode 140A (see first electrode 42, FIG. 5 and FIG. 14), and the first electrode 140B (see second electrode 54, FIG. 5 and FIG. 14). The third contact hole opening 137C penetrates the insulating layers 136 and exposes the second wiring 133B. The first electrode 140C is electrically connected to the second wiring 133B via the third contact hole opening 137C. For example, the first electrode 140C also serves as a pixel electrode. The third contact hole opening 137B penetrates the insulating layers 136 and exposes the second wiring 133B. The first electrode 140A is electrically connected to the second wiring 133B via the third contact hole opening 137B. Further, although not shown, for example, the third contact hole opening 137 exposes part of a plurality of terminals (not shown) included in the terminal portion 150. Part of the exposed terminals are electrically connected to the FPC 200 using a conductive film such as an anisotropic conductive film (not shown). Further, the pixel electrodes are arranged independently for each pixel.

An insulating layer 131 is arranged on the insulating layer 136 where the conductive layer 140 is not arranged, and is arranged so as to cover the conductive layer 140. The fourth contact hole opening 129 is arranged in the insulating layers 131 and 136. The conductive layer 142 is arranged on the insulating layer 131 and in the fourth contact hole opening 129. The conductive layer 142 includes the second electrode 142A (the first electrode 52 and the second electrode 44). The fourth contact hole opening 129 penetrates the insulating layers 131 and 136 and exposes the second wiring 133F. The second electrode 142A is electrically connected to the second wiring 133F via the fourth contact hole opening 129.

For example, the capacitive element CV is formed using the insulating layer 131 as a dielectric and using the first electrode 140A (see the first electrode 42, FIG. 5 and FIG. 14) and the second electrode 142A (see the second electrode 44, FIG. 5 and FIG. 14), and the capacitive element CD is formed using the insulating layer 131 as a dielectric and using the first electrode 140B (see the second electrode 54, FIG. 5 and FIG. 14) and the second electrode 142A (see the first electrode 52, FIG. 5 and FIG. 14). The capacitive element CV is arranged adjacent to the capacitive element CD along the first direction D1.

The insulating layer 141 is arranged on the insulating layer 131 where the conductive layer 142 is not arranged, and is arranged so as to cover the conductive layer 142.

For example, the base layer 121, the semiconductor layer 122, the gate insulating layer 125, the conductive layer 127, the insulating layer 128, the conductive layer 132, the insulating layer 139, the conductive layer 133, the insulating layer 136, the conductive layer 140, the insulating layer 131, the conductive layer 142, and the insulating layer 141 are collectively referred to as an array portion 170.

Next, a plurality of layers stacked on the insulating layer 141 will be described. The contact hole opening 147 for the anode is arranged in the insulating layer 141. The contact hole opening 147 for the anode includes the contact hole opening 147A for the anode. The contact hole opening 147A for the anode penetrates through the insulating layers 141 and 131 and is arranged in the insulating layers 141 and 131 to expose the conductive layer 140 (for example, the first electrode 140C).

The anode 143 is arranged to cover the exposed first electrode 140C, the contact hole opening 147A for the anode, and the insulating layers 141 and 131. The functional layer 148 is arranged on the anode 143. The cathode 149 (first electrode 32 of the light-emitting device OLED, see FIG. 3) is arranged on the functional layer 148 so as to cover the functional layer 148. The cathode 149 is electrically connected to the standard potential line PVSS. Here, the light-emitting device OLED includes the anode 143, the functional layers 148, and the cathode 149.

The configuration of the functional layer 148 can be selected as appropriate. For example, the functional layer 148 may be formed by combining a carrier injection layer, a carrier transport layer, a light-emitting layer, a carrier blocking layer, an exciton blocking layer, and the like. For example, the functional layer 148 shown in FIG. 7 includes the first layer 144, a second layer 145, and a third layer 146. For example, the first layer 144 is a carrier (hole) injection and transport layer, the second layer 145 is a light-emitting layer, and the third layer 146 is a carrier (electron) injection and transport layer. For example, the functional layer 148 is arranged independently for each pixel, similar to the pixel electrode.

The sealing film 165 is arranged on the cathode 149. For example, the sealing film 165 includes a first inorganic insulating layer 152, an organic insulating layer 154, and a second inorganic insulating layer 156. The first inorganic insulating layer 152 and the second inorganic insulating layer 156 are formed so as to cover at least the display region 22. The cover film 158 is arranged over the second inorganic insulating layer 156.

For example, the first layer 144, the second layer 145 (light-emitting layer) the third layer 146, and the anode 143 included in the functional layer 148 are not arranged on the IC chip 110 and the control circuit 120. Above the IC chip 110 and the control circuit 120, the sealing film 165 and the cover film 158 are arranged. The sealing film 165 and the cover film 158 prevent impurities (water, oxygen, and the like) from entering the light-emitting device OLED and the transistors from the outside of the display device 10.

Further, for example, as shown in FIG. 5, the second electrode 142A also serves as the second electrode 44 of the capacitive element CV and the first electrode 52 of the capacitive element CD, an area of the second electrode 142A is larger than a sum of an area of the first electrode 140A and an area of the first electrode 140B, and the second electrode 142A overlaps the first electrode 140A and the first electrode 140B. As shown in FIG. 7, the end portion 142E of the second electrode 142A covers an end portion 140E of the first electrode 140A. Further, as shown in FIG. 9, the end portion 142E of the second electrode 142A covers the end portion 140BE of the first electrode 140B.

Consequently, a capacitance is formed by the end portion 142E of the second electrode 142A, the end portion 140E of the first electrode 140A, and the insulating layer 131 sandwiched between the end portion 142E of the second electrode 142A and the end portion 140E of the first electrode 140A. Therefore, the pixel 180 including a configuration covering the end portion of the electrode forming the capacitance can increase the capacitance value of the capacitive element more than a pixel including a configuration not covering the end portion of the electrode forming the capacitance. As a result, it is possible to suppress a decrease in the potential held by the capacitive element or a loss in the potential held by the capacitive element.

### [1-6. Manufacturing Method of Display Device 10]

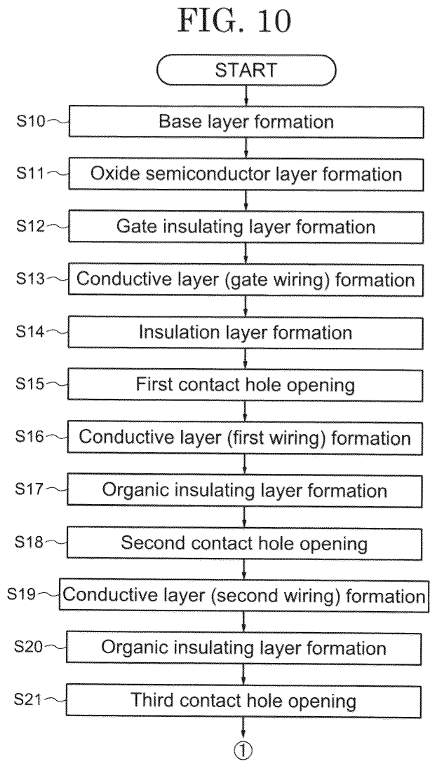

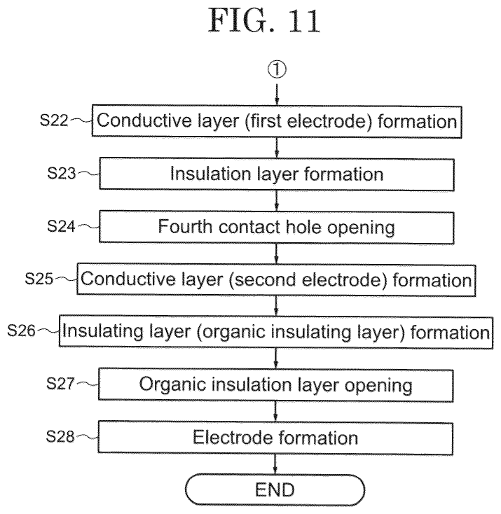

A method for manufacturing the display device 10 (pixel 180) will be described with reference to FIG. 4 to FIG. 6 and FIG. 10 to FIG. 14. FIG. 10 and FIG. 11 are sequence diagrams showing the method for manufacturing the display device 10. FIG. 12 to FIG. 14 are diagrams showing the pixels 180 when the display device 10 is viewed from the front side (the first surface 101A). Configurations that are the same as or similar to those in FIG. 1 to FIG. 13 will be described as necessary, and description of the same or similar configurations as those in FIG. 1 to FIG. 13 may be omitted. The method for manufacturing the display device 10 includes, for example, that the semiconductor layer is an oxide semiconductor layer formed using an oxide semiconductor.

When manufacturing of the display device 10 (pixel 180) is started, the base layer 121 (see FIGS. 7 to 9) is formed on the first surface 101A (see FIG. 7 to FIG. 9) of the substrate 101 (see FIG. 7 to FIG. 9) (step 10 (S10) in FIG. 10). For example, the substrate 101 is a glass substrate.

As shown in FIG. 12, the semiconductor layer 122 includes the semiconductor layers 122A, 122B, 122C, 122D, and 122E. The semiconductor layer 122A is a semiconductor layer of the first transistor T1. The semiconductor layer 122B includes the semiconductor layer 122BA arranged along the first direction D1, the semiconductor layer 122BB arranged along the second direction D2 and connected to the semiconductor layer 122BA, and the semiconductor layer 122BC arranged along the first direction D1 and connected to the semiconductor layer BB, and serves as a semiconductor layer of the second transistor T2 and a semiconductor layer of the fifth transistor T5. The semiconductor layer 122C is a semiconductor layer of the third transistor T3. The semiconductor layer 122D is a semiconductor layer of the fourth transistor T4. The semiconductor layer 122E is a semiconductor layer of the sixth transistor T6. In other words, the semiconductor layer 122A includes the channel region of the first transistor T1, the semiconductor layer 122B includes the channel region of the second transistor T2 and a channel region of the fifth transistor T5, the semiconductor layer 122C includes a channel region of the third transistor T3, the semiconductor layer 122D includes a channel region of the fourth transistor T4, and the semiconductor layer 122E includes a channel region of the sixth transistor T6. Further, the first electrode and the second electrode of each transistor include an impurity region. That is, the first electrode 614 and the second electrode 616 of the first transistor T1, the first electrode 624 and the second electrode 626 of the second transistor T2, the first electrode 634 and the second electrode 636 of the third transistor T3, the first electrode 644 and the second electrode 646 of the fourth transistor T4, and the first electrode 654 and the second electrode 656 of the fifth transistor T5 include impurity regions. In other words, the semiconductor layer 122A includes the channel region of the first transistor T1, the semiconductor layer 122B includes the channel region of the second transistor T2 and the channel region of the fifth transistor T5, the semiconductor layer 122C includes the channel region of the third transistor T3, the semiconductor layer 122D includes the channel region of the fourth transistor T4, and the semiconductor layer 122E includes the channel region of the sixth transistor T6.

The gate insulating layer 125 (see FIG. 7 to FIG. 9) is formed on the semiconductor layer 122 and on the base layer 121 on which the semiconductor layer 122 is not formed (step 12 (S12) in FIG. 10).

The conductive layer 127 (see FIG. 7 to FIG. 13) is formed over the gate insulating layer 125 (see FIG. 7 to FIG. 9) (step 13 (S13) of FIG. 10). As shown in FIG. 4, FIG. 12, and FIG. 13, the conductive layer 127 includes the gate wiring 127A (the scan signal line 332) , the gate wiring 127B (the gate electrode 622), a gate wiring 127C (the scan signal line 331), a gate wiring 127D (the scan signal line 333), a gate wiring 127E (the scan signal line 334), a gate wiring 127F (the scan signal line 330), and the gate wiring 127G (the signal line to which the scan signal SC4(n−1) is supplied). The gate wiring 127A includes the gate electrode 612, the gate wiring 127B includes the gate electrode 622, the gate wiring 127C includes the gate electrode 632, the gate wiring 127D includes the gate electrode 642, the gate wiring 127E includes the gate electrode 652, and the gate wiring 127F includes the gate electrode 662.

A region where the gate electrode 622 of the second transistor T2 and the semiconductor layer 122B overlap each other is the channel region 123, and the channel region 123 corresponds to a channel length of the second transistor T2. Similar to the second transistor T2, a region where the gate electrode 612 of the first transistor T1 and the semiconductor layer 122A overlap each other is the channel region of the first transistor T1 and corresponds to a channel length. Similar to the second transistor T2 and the first transistor T1, each of the transistors other than the second transistor T2 and the first transistor T1 has a region in which the gate electrode and the semiconductor layer overlap each other, which is the channel region of the transistor and corresponds to a channel length.

As shown in FIG. 12, in a plan view, the channel region 123 of the second transistor T2 is larger (longer) than the channel region of the first transistor T1, the channel region of the third transistor T3, the channel region of the fourth transistor T4, the channel region of the fifth transistor T5, and the channel region of the sixth transistor T6. That is, the channel length of the second transistor T2 is longer than the channel length of the first transistor T1, the channel length of the third transistor T3, the channel length of the fourth transistor T4, the channel length of the fifth transistor T5, and the channel length of the sixth transistor T6. Since the second transistor T2 operates in a saturated region, a kink effect needs to be suppressed. Furthermore, resistance of the second transistor T2 to hot carriers is preferably higher than resistance of other transistors in the pixel 180 to hot carriers. The channel length of the second transistor T2 is longer than the channel length of the other transistors in the pixel 180 in order to suppress the kink effect and ensure reliability (hot carrier resistance).

The insulating layer 128 (see FIG. 7 to FIG. 9) is formed over the conductive layer 127 and over the gate insulating layer 125 where the conductive layer 127 is not formed (step 14 (S14) of FIG. 10).

As shown in FIG. 4, FIG. 12, and FIG. 13, first contact hole openings 135A to 135J are opened (step 15 (S15) in FIG. 10). Each opening may open the gate insulating layer 125 and the insulating layer 128 to expose the semiconductor layer, and each opening may open the insulating layer 128 to expose the gate wiring. For example, the first contact hole openings 135A and 135B expose the semiconductor layer 122A, the first contact hole opening 135C exposes the semiconductor layer 122B, the first contact hole openings 135D and 135E expose the semiconductor layer 122C, the first contact hole openings 135F and 135G expose the semiconductor layer 122B, and the first contact hole openings 135I and 135J expose the semiconductor layer 122E. The first contact hole opening 135B exposes the gate line 127B. Other openings also expose corresponding semiconductor layers or gate lines.

The conductive layer 132 (see FIG. 7 to FIG. 9) is formed on the insulating layer 128 or in the first contact hole opening 135 (step 16 (S16) in FIG. 10). As shown in FIG. 4 and FIG. 13, the conductive layers 132 include a first wiring 132A (image data signal line 321), the first wiring 132B, the first wiring 132C, a first wiring 132D, a first wiring 132E, a first wiring 132F, the first wiring 132G (driving potential line PVDD), a first wiring 132H, the first wiring 132I, and the first wiring 132J (driving potential line PVDD).

As shown in FIG. 13, in a plan view, for example, the first wiring 132A is electrically connected to the first transistor T1 via the first contact hole opening 135A. The first wiring 132B is electrically connected to the first transistor T1 and the gate wiring 127B via the first contact hole opening 135B. The first wiring 132C is electrically connected to the second transistor T2 via the first contact hole opening 135C, and is electrically connected to the fourth transistor T4 via the first contact hole opening 135F. The first wiring 132D is electrically connected to the third transistor T3 via the first contact hole opening 135D. The first wiring 132E is electrically connected to the third transistor T3 via the first contact hole opening 135E. The first wiring 132F is electrically connected to the fourth transistor T4 via the first contact hole opening 135G. The first wiring 132G is electrically connected to the fifth transistor T5 via the first contact hole opening 135H. The first wiring 132H is electrically connected to the sixth transistor T6 via the first contact hole opening 135I. The first wiring 132I is electrically connected to the sixth transistor T6 via the first contact hole opening 135J. The first wiring 132J is electrically connected to a first transistor T1 (not shown) arranged in a first region of one of the plurality of pixels 180 arranged in an (m+1)th column. The other first wiring is also electrically connected to the gate wiring or the transistor (the semiconductor layer 122) via the corresponding opening.

The insulating layer 139 (see FIG. 7 to FIG. 9) is formed over the conductive layer 132 and over the insulating layer 128 where the conductive layer 132 is not formed (step 17 (S17) of FIG. 10).

As shown in FIG. 4 and FIG. 13, the second contact hole opening 138 is opened (step 18 (S18) in FIG. 10). The second contact hole opening 138 includes second contact hole openings 138A to 138H.

As shown in FIG. 13, in a plan view, for example, the second contact hole opening 138A exposes the first wiring 132B. The second contact hole opening 138B exposes the first wiring 132E. The second contact hole opening 138C exposes the first wiring 132C. The second contact hole opening 138D exposes the first wiring 132D. The second contact hole opening 138E exposes the first wiring 132F. The second contact hole opening 138F exposes the first wiring 132I. The second contact hole opening 138G exposes the first wiring 132H. Each opening opens the insulating layer 136 to expose the first wiring corresponding to each opening.

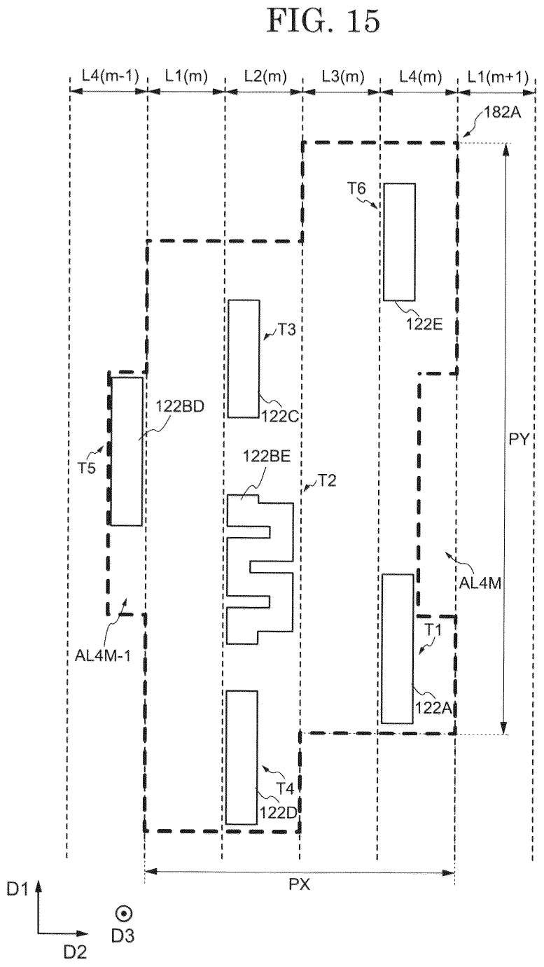

The conductive layer 133 (see FIG. 7 to FIG. 9) is formed over the insulating layer 139 (see FIG. 7 to FIG. 9) and in the second contact hole opening 138 (step 19 (S19) of FIG. 10). As shown in FIG. 4, FIG. 5, FIG. 14, and FIG. 15, the conductive layers 133 include a second wiring 133A, the second wiring 133B, a second wiring 133C (reset potential line SVRE), a second wiring 133D (initialization potential line SVI), a second wiring 133E (reference potential line SVR), and the second wiring 133F.

As shown in FIG. 4, FIG. 5, FIG. 14, and FIG. 15, in a plan view, for example, the second wiring 133A is electrically connected to the first wiring 132B via the second contact hole opening 138A. The second wiring 133B is electrically connected to the second transistor T2 and the fourth transistor T4 via the second contact hole opening 138C. The second wiring 133C is electrically connected to the first wiring 132D via the second contact hole opening 138D. The second wiring 133D is electrically connected to the fourth transistor T4 via the second contact hole opening 138E. The second wiring 133E is electrically connected to the first wiring 132H via the second contact hole opening 138H. The second wiring 133F is electrically connected to the first wiring 132I via the second contact hole opening 138F. The other second wiring lines are also electrically connected to the first wiring lines via the respective openings.

The insulating layer 136 (see FIG. 7 to FIG. 9) is formed over the conductive layer 133 and over the insulating layer 139 where the conductive layer 133 is not formed (step 20 (S20) of FIG. 10).

As shown in FIG. 4, FIG. 5, and FIG. 14, the third contact hole opening 137 is opened (step 21 (S21) in FIG. 10). The third contact hole opening 137 includes third contact hole openings 137A to 137C.

As shown in FIG. 4, FIG. 5, and FIG. 14, in a plan view, for example, the third contact hole opening 137A exposes the second wiring 133A. The third contact hole openings 137B and 137C expose the second wiring 133B. Each opening opens the insulating layer 136 to expose the first wiring corresponding to each opening.

The conductive layer 140 (see FIG. 7 and FIG. 9) is formed on the insulating layer 136 (see FIG. 7 to FIG. 13) and in the second contact hole opening 138 (step 22 (S22) in FIG. 11). As shown in FIG. 4, FIG. 5, and FIG. 14, the conductive layer 140 includes the first electrode 140A (first electrode 42), the first electrode 140B (second electrode 54), and the first electrode 140C (second electrode 34).

As shown in FIG. 5 or FIG. 14, in a plan view, for example, the first electrode 140A is electrically connected to the second wiring 133B via the third contact hole opening 137B. The first electrode 140B is electrically connected to the second wiring 133A via the third contact hole opening 137A. The first electrode 140C is electrically connected to the second wiring 133B via the third contact hole opening 137C. The other first electrodes are also electrically connected to the second wirings via corresponding openings. The first electrode 140A is arranged adjacent to the second electrode 140B along the first direction D1.

The insulating layer 131 (see FIG. 7 and FIG. 9) is formed over the conductive layer 140 and over the insulating layer 136 without the conductive layer 140 (step 23 (S23) of FIG. 10).

As shown in FIG. 5 or FIG. 14, the fourth contact hole opening 129 is opened (step 24 (S24) in FIG. 10). The fourth contact hole opening 129 opens the insulating layers 131 and 136 to expose the conductive layer 133.

For example, the fourth contact hole opening 129 exposes the second wiring 133F. The other third contact hole openings also expose the respective insulating layers, wirings, or electrodes.

The conductive layer 142 (see FIG. 7 or FIG. 9) is formed over the insulating layer 131 (see FIG. 7 to FIG. 9) and in the fourth contact hole opening 129 (step 25 (S25) of FIG. 10). For example, as shown in FIG. 5, the conductive layer 142 includes the second electrode 142A (second electrode 44, first electrode 52). The second electrode 142A is electrically connected to the second wiring 133F via the fourth contact hole opening 129. The other conductive layers 142 are also electrically connected to the corresponding second wirings and electrically connected to the corresponding gate wirings or transistors in the same manner as the second electrode 142A.

The insulating layer 141 (organic insulating layer) (see FIG. 7 to FIG. 9) is formed on the conductive layer 142 and on the insulating layer 131 on which the conductive layer 142 is not formed (step 26 (S26) in FIG. 10).

Further, the insulating layer 141 (organic insulating layer) and the insulating layer 131 (see FIG. 8) are opened (step 27 (S27) in FIG. 10). In the opening of S27, the contact hole opening 147A for the anode is opened. The contact hole opening 147A for the anode removes the insulating layers 141 and 131 on the first electrode 140C to expose the first electrode 140C. The contact hole opening 147A for the anode may be referred to as an organic insulating layer opening.

The anode 143 (see FIG. 7) is arranged over the exposed first electrode 140C, over the contact hole opening 147A for the anode, and over the insulating layers 141 and 131 (step 28 (S28) of FIG. 10). The functional layer 148 (see FIG. 7) is also arranged on the anode 143. The cathode 149 (see FIG. 7) is arranged over the functional layer 148. For example, the anode 143 may be arranged for each pixel, the functional layer 148 may be arranged for each pixel, and the cathode 149 may be arranged so as to overlap the display region 22.

After S28, the sealing film 165 is arranged over the cathode 149 and the cover film 158 is arranged over the sealing film 165 (see FIG. 7). That is, the sealing film 165 and the cover film 158 are arranged on the cathode 149 in this order (see FIG. 7).

As described above, the manufacturing of the display device 10 (pixel 180) is completed.

The method for manufacturing the display device 10 (pixel 180) includes forming the semiconductor layer 122 in the second region L2 (m), the fourth region L4 (m), and the fourth region L4 (m−1) generally along the first direction D1 (see FIG. 4 and FIG. 6), forming the conductive layer 132 generally along the first direction D1 (see FIG. 4 and FIG. 6), forming the conductive layer 127 generally along the second direction D2 (see FIG. 4 and FIG. 6), and forming the conductive layer 133 generally along the second direction D2. In addition, the method for manufacturing the display device 10 (pixel 180) includes forming the conductive layer 140 and forming the conductive layer 142. The wirings that are routed through the display device 10 are mainly formed by the conductive layer 127, the conductive layer 132, and the conductive layer 133, and the capacitive elements CV and CD and the anode 143 are formed using the conductive layer 140 or the conductive layer 142. That is, in the method for manufacturing the display device 10 (the pixel 180), formation of a lead wiring and formation of the capacitive element can be formed using different wirings or electrodes. Therefore, in the method for manufacturing the display device 10 (pixel 180), the capacitive elements CV and CD included in the pixels and the capacitive elements CV and CD included in the adjacent pixels can be arranged at positions as close as possible. In addition, since the conductive layer 140 and the conductive layer 142 are generally used to form the capacitive elements CV and CD, the capacitance of the capacitive element can be increased in the method for manufacturing the display device 10 (pixel 180).

As a result, in the method for manufacturing the display device 10 (pixel 180), it is possible to achieve higher definition and to suppress a decrease in the potential held by the capacitive element or a loss in the potential held by the capacitive element than in the case where the lead wiring and the formation of the capacitive element are not formed by using mutually different wirings or electrodes.

### [1-7. Material of Each Member of Display Device 10]

As the substrate 101, a rigid substrate having a light-transmitting characteristic and no flexibility, such as a glass substrate, a quartz substrate, or a sapphire substrate, can be used. In the case where the substrate 101 needs to have flexibility, a flexible substrate including a resin such as a polyimide substrate, an acrylic substrate, a siloxane substrate, or a fluorine resin substrate can be used as the substrate 101. In order to improve the heat resistance of the substrate SUB, the resin may be doped with impurities.

For example, the semiconductive layers 122 include channel regions and include Group 14 elements such as silicon (Si), germanium (Ge), or oxides exhibiting semiconductor characteristics. As an oxide exhibiting semiconductor characteristics, a metal oxide having semiconductor characteristics can be used. For example, as described in “1-6. Manufacturing Method of Display Device 10”, the semiconductive layer 122 includes an oxide semiconductor as a metal oxide exhibiting semiconductor characteristics. For example, the oxide semiconductor includes two or more metals including indium (In). In addition to indium, gallium (Ga), zinc (Zn), aluminum (Al), hafnium (Hf), yttrium (Y), zirconia (Zr), and lanthanoids may be used as the metal oxide having semiconductive characteristics. Further, the metal oxide having semiconductor characteristics may be amorphous, may be crystalline, or may be a mixed phase of amorphous and crystalline.

Further, for example, the semiconductive layer 122 including the Group 14 element may include crystalline silicon. The crystalline silicon may be low-temperature polysilicon (LTPS) or single-crystal silicon. The crystalline silicon is implanted with impurities. For example, in the case where the transistor is an n-channel field-effect transistor, impurities (for example, phosphorus (P)) are implanted so that the crystalline silicon becomes an n-type. In addition, the channel regions of the transistors included in the display device 10 may be formed using single-crystal silicon such as a silicon wafer or an SOI substrate.

For example, the leakage current of a transistor including a metal oxide having semiconductor characteristics is extremely small. Therefore, by using a transistor having a metal oxide having semiconductor characteristics, a charge corresponding to the potential written in the capacitive element is less likely to escape from the capacitive element. As a result, by using a transistor having a metal oxide having semiconductor characteristics, it is possible to hold the charge written in the capacitive element for a long time. In addition, if a gate-source potential difference (a potential difference between the gate electrode and the source electrode) and a source-drain potential difference are the same, a drain current of the transistor having the metal oxide having the semiconductor characteristic may be larger than the drain current of the transistor having the crystalline silicon (for example, low-temperature polysilicon (LTPS)). As a result, under the same condition of the drain current, the gate-source potential difference and the source-drain potential difference of the transistor having the metal oxide having the semiconductor characteristics can be made smaller than the transistor having the crystalline silicon. Therefore, by using a transistor having a metal oxide having semiconductor characteristics, power consumption of the display device 10 can be suppressed.

A general metal material is used as the conductive layer 127, the conductive layer 132, the conductive layer 133, the conductive layer 140, and the conductive layer 142. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as common metallic materials. In addition, depending on the application and specifications of the display device 10, each conductive layer may include a structure in which the metal material described above is a single layer, and may include a structure (multi-layer structure) in which the metal material described above is laminated. For example, the conductive layer 140 including the first electrode includes the configuration in which the metal material is a single layer, and the conductive layer 142 including the second electrode includes the configuration in which the metal material is laminated.

A general insulating material can be used as a material for forming the base layer 121, the gate insulating layer 125, the insulating layer 131, the first inorganic insulating layer 152, and the second inorganic insulating layer 156. For example, inorganic insulating layers such as silicon oxide (SiOₓ), silicon oxynitride (SiOₓN_{y}), silicon nitride (SiNₓ), and silicon nitride oxide (SiNₓO_{y}) are used as the insulating layers. The SiOₓN_{y} is a silicon compound that contains a smaller proportion (x>y) of nitrogen (N) than oxygen (O). The SiNₓO_{y} is a silicon compound that contains a smaller proportion (x>y) of oxygen than nitrogen.

For example, as materials for forming the insulating layer 128, the insulating layer 139, the insulating layer 136, the insulating layer 141, and the organic insulating layer 154, an organic compound material having excellent surface flatness can be used. The insulating layer 128, the insulating layer 136, and the insulating layer 141 may be referred to as an organic insulating layer.

As a material forming the cathode 149, a conductive oxide that transmits visible light is used. For example, the cathode 149 may be formed of a mixture of indium oxide and tin oxide (ITO) or a mixture of indium oxide and zinc oxide (IZO). A material other than the above may be used as the conductive oxide that transmits visible light.

As a material for forming the anode 143, a metal having a high reflectance or an alloy thereof is used. For example, the anode 143 may be formed of a metal such as silver (Ag), aluminum (Al), or magnesium (Mg), or an alloy thereof. The material forming the anode 143 may include a structure in which a film containing a metal is sandwiched between the conductive oxide containing films.

### [1-8. Modification of Structure of Pixel 180]

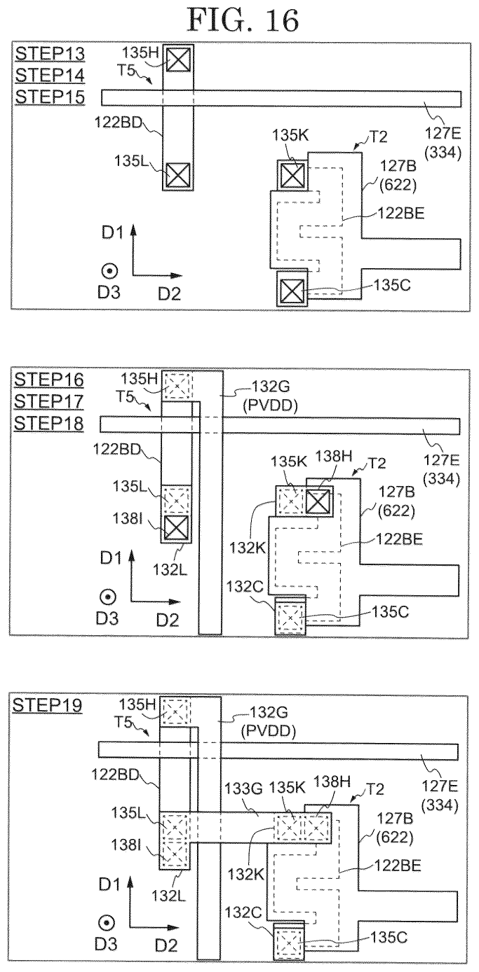

A modification of the structure of the pixel 180 will be described with reference to FIG. 15 and FIG. 16. FIG. 15 is a plan view showing the semiconductive layer 122 in the modification of the structure of the pixel 180. FIG. 16 is a layout diagram showing S13 to S19 in “1-6. Manufacturing Method of Display Device 10” by extracting the fifth transistor T5 and the periphery of the second transistor T2 shown in FIG. 15. Configurations that are the same as or similar to those in FIG. 1 to FIG. 14 will be described as necessary.

The modification of the structure of the pixel 180 is mainly different from the configuration described in “1-5. Structure of Pixel 180” in the configurations 1 to 3 shown below.
(Configuration 1) A configuration in which the semiconductive layer 122B of the configuration described with reference to FIG. 6 in “1-5. Structure of Pixel 180” is separated into a semiconductive layer 122BD and a semiconductive layer 122BE.
(Configuration 2) Configuration of gate wiring 127B (gate electrode 622).
(Configuration 3) First contact hole openings 135L and 135K, first wirings 132L and 132K, second contact hole openings 138H and 138I, and a second wiring 133G are included by the configuration 1.

Configurations other than those shown in Configuration 1 to Configuration 3 and configurations other than those related to configurations shown in Configuration 1 to Configuration 3 are the same configurations as those described in “1-1. Overview of Display Device 10” to “1-7. Material of Each Member of Display Device 10”. In describing the configuration and function of a modification of the structure of the pixel 180, the same configuration and function as those of the pixel 180 will be described as necessary.

As shown in FIG. 15, the first region L1(m) in the modification of the configuration of the pixel 180 does not include a semiconductive layer. The second region L2(m) includes the semiconductive layer 122C, the semiconductive layer 122BE, and the semiconductive layer 122D along the first direction. The third region L3(m) does not include semiconductive layers. The fourth region L4(m) includes the semiconductive layers 122E and 122A along the first orientation. The fourth region L4(m−1) includes the semiconductive layer 122BD along the first orientation.

The semiconductive layer 122 includes the semiconductive layers 122A, 122BD, 122BE, 122C, 122D, and 122E. The configurations of the semiconductor layers 122A, 122C, 122D, and 122E are the same as those described in “1-5. Structure of Pixel 180”.

The semiconductive layer 122BE arranged along the first direction D1 is a semiconductive layer of the second transistor T2. The semiconductive layer 122BD arranged along the first direction D1 is a semiconductive layer of the fifth transistor T5. In other words, the semiconductive layer 122BE includes the channel region of the second transistor T2, and the semiconductive layer 122BD includes the channel region of the fifth transistor T5. The semiconductive layer 122BE has a serpentine configuration along the first direction D1 and includes a plurality of bend portions.

As shown in STEP13 (S13 shown in FIG. 10) of FIG. 16, the gate wiring 127E (scan signal line 334) and the gate wiring 127B (gate electrode 622) are formed. The gate wiring 127B overlaps a portion of the semiconductive layer 122BE except in the vicinity of the regions where the first contact hole openings 135K and 135C are arranged, and covers a portion of the semiconductive layer 122BE. Referring to FIG. 4, FIG. 6, and FIG. 15, the gate wiring 127B slightly overlaps the first region L1(m), overlaps the second region L2(m), the third region L3(m), and the fourth region L4(m), and does not overlap the fourth region L4(m−1).

In STEP14 (S14 shown in FIG. 10), the insulating layer 128 (FIG. 7 to FIG. 9) is formed. As shown in STEP15 (S13 shown in FIG. 10) of FIG. 16, first contact hole openings 135H, 135L, 135K, and 135C are formed. The first contact hole openings 135H and 135L open the semiconductive layer 122BD and expose the semiconductive layer 122BD, and the first contact hole openings 135K and 135C open the semiconductive layer 122BE and expose the semiconductive layer 122BE.

As shown in STEP16 (S16 shown in FIG. 10) of FIG. 16, the first wiring 132G (driving potential line PVDD), and the first wirings 132L, 132K, and 132C are formed. The first wiring 132G is formed on the first contact hole opening 135H and the semiconductive layer 122BD, and is electrically connected to the semiconductive layer 122BD. The first wiring 132L is formed on the first contact hole opening 135L and the semiconductive layer 122BD, and is electrically connected to the semiconductive layer 122BD. The first wiring 132K is formed on the first contact hole opening 135K and the semiconductive layer 122BE, and is electrically connected to the semiconductive layer 122BE. The first wiring 132C is formed on the first contact hole opening 135C and the semiconductive layer 122BE, and is electrically connected to the semiconductive layer 122BE.

In STEP17 (S17 shown in FIG. 10), the insulating layer 139 (FIG. 7 to FIG. 9) are formed. As shown in STEP18 (S18 shown in FIG. 10) of FIG. 16, second contact hole openings 138H and 138I are formed. The second contact hole opening 138H opens the first wiring 132K and exposes the first wiring 132K, and the second contact hole opening 138I opens the first wiring 132L and exposes the first wiring 132L.

As shown in STEP19 of FIG. 16 (S19 shown in FIG. 10), the second wiring 133G is formed. The second wiring 133G is formed on the second contact hole openings 138H and 138I, and is electrically connected to the semiconductive layer 122BD and the semiconductive layer 122BE. That is, the second wiring 133G is a bridge wiring that overlaps a portion of the first wiring 132G and electrically connects the second transistor T2 and the fifth transistor T5 across the first wiring 132G.

In a modification of the configuration of the pixel 180, the second transistor T2 and the fifth transistor T5 can be electrically connected across the first wiring 132G by using the second wiring 133G, so that the second region L2(m) can be configured to not include the semiconductive layer.

Other configurations in the modified example of the structure of the pixel 180 are the same configurations as those described in “1-1. Overview of Display Device 10” to “1-7. Material of Each Member of Display Device 10”. Variations of the structure of the pixel 180 have the same operational effects as those described in “1-1. Overview of Display Device 10” to “1-7. Material of Each Member of Display Device 10”.

As the embodiment of the present invention, each of the embodiments described above or a part of each of the embodiments described above can be appropriately combined as long as they do not conflict with each other.

It is to be understood that the present invention provides other functional effects that are different from the operational effects provided by the aspects of the embodiments described above, and those that are obvious from the description of the present specification or those that can be easily predicted by a person skilled in the art.

What is claimed is:

1. A display device comprising:
a plurality of pixels arranged in a matrix in a first direction and a second direction intersecting the first direction; and
a plurality of individual semiconductor layers arranged along the first direction for each of the plurality of pixels,
wherein
each of the plurality of pixels includes a first region, a second region adjacent to the first region, a third region adjacent to the second region, and a fourth region adjacent to the third region,
the first region, the second region, the third region, and the fourth region are arranged along the first direction,
at least one semiconductor layer of the plurality of individual semiconductor layers is arranged in the second region, and
at least one other semiconductor layer of the plurality of individual semiconductor layers is arranged in the fourth region.

2. The display device according to claim 1, wherein
the plurality of individual semiconductor layers includes a first semiconductor layer, a second semiconductor layer, a third semiconductor layer, a fourth semiconductor layer, a fifth semiconductor layer, and a sixth semiconductor layer,
the first to the sixth semiconductor layers are arranged along the first direction,
the second to the fourth semiconductor layers overlap with the second region, and, and
the first semiconductor layer, the fifth semiconductor layer, and the sixth semiconductor layer overlap with the fourth region.

3. The display device according to claim 2, wherein
each of the plurality of pixels includes a first transistor, a second transistor, a third transistor, a fourth transistor, a fifth transistor, a sixth transistor, a first capacitive element, a second capacitive element, and a light-emitting element,
the first transistor includes the first semiconductor layer,
the second transistor includes the second semiconductor layer,
the third transistor includes the third semiconductor layer,
the fourth transistor includes the fourth semiconductor layer,
the fifth transistor includes the fifth semiconductor layer, and
the sixth transistor includes the sixth semiconductor layer.

4. The display device according to claim 3, further comprising a second conductive layer overlapping the plurality of individual semiconductor layers in a planar view,
wherein
the second conductive layer includes a first portion and a second portion,
the first portion of the second conductive layer overlaps the third region and serves as an image data signal line for supplying a data potential to the first transistor, and
the second portion of the second conductive layer overlaps the first region and serves as a drive potential line for supplying a drive potential for driving the plurality of pixels to the fifth transistor.

5. The display device according to claim 4, further comprising
a first conductive layer arranged along the second direction, between the plurality of individual semiconductor layers and the second conductive layer,
wherein
the first conductive layer includes a first portion, a second portion, a third portion, a fourth portion, a fifth portion, and a sixth portion,
the first portion of the first conductive layer overlaps the first region to the fourth region and the first transistor and is a signal line for supplying a first control signal for controlling switching of the first transistor,
the second portion of the first conductive layer overlaps the second region to the fourth region and the second transistor and is a gate electrode for controlling switching of the second transistor,
the third portion of the first conductive layer overlaps the first region to the fourth region and the third transistor and is a signal line for supplying a second control signal for controlling switching of the third transistor,
the fourth portion of the first conductive layer overlaps the first region to the fourth region and the fourth transistor and is a signal line for supplying a third control signal for controlling switching of the fourth transistor,
the fifth portion of the first conductive layer overlaps the first region to the fourth region and the fifth transistor and is a signal line for supplying a fourth control signal for controlling switching of the fifth transistor, and
the sixth portion of the first conductive layer overlaps the first region to the fourth region and the sixth transistor and is a signal line for supplying a fifth control signal for controlling switching of the sixth transistor.

6. The display device according to claim 5, further comprising a third conductive layer arranged on the plurality of individual semiconductor layers along a third direction intersecting the first direction and the second direction,
wherein
the third conductive layer includes a first portion, a second portion, and a third portion,
the first portion of the third conductive layer overlaps the first region to the fourth region, is electrically connected to the third transistor, and serves as a reset potential line for supplying a reset potential for supplying a reference potential to the third transistor,
the second portion of the third conductive layer overlaps the first region to the fourth region, is electrically connected to the fourth transistor, and serves as an initialization potential line for supplying an initialization potential to the fourth transistor, and
the third portion of the third conductive layer overlaps the first region to the fourth region, is electrically connected to the sixth transistor, and serves as a reference potential line for supplying a reference potential to the sixth transistor.

7. The display device according to claim 6, further comprising:
a fourth conductive layer arranged on the third conductive layer, along the third direction;
a fifth conductive layer arranged on the fourth conductive layer, along the third direction; and
an insulating layer arranged between the fourth conductive layer and the fifth conductive layer, along the third direction,
wherein
the fourth conductive layer includes a first portion, a second portion, and a third portion, and
the fifth conductive layer includes a first portion.

8. The display device according to claim 7, wherein
the first portion of the fourth conductive layer is arranged adjacent to the second portion of the fourth conductive layer along the first direction,
the first capacitance element includes the first portion of the fourth conductive layer, a portion of the insulating layer, and a portion of the first portion of the fifth conductive layer, and
the second capacitance element includes the second portion of the fourth conductive layer, another portion of the insulating layer, and another portion of the first portion of the fifth conductive layer.

9. The display device according to claim 7, wherein
the first portion of the fifth conductive layer overlaps and covers the first portion and the second portion of the fourth conductive layer.

10. The display device according to claim 7, further comprising an anode layer arranged on the fifth conductive layer, wherein
the light-emitting element includes a third portion of the fourth conductive layer and a portion of the anode layer electrically connected to the third portion of the fourth conductive layer.

11. The display device according to claim 3, wherein
the plurality of pixels includes at least a first pixel and a second pixel adjacent to each other along the second direction, and
the fifth semiconductor layer of the second pixel is arranged in a fourth region of the first pixel.

12. The display device according to claim 3, wherein
the first transistor, the second transistor, the third transistor, the fourth transistor, the fifth transistor, and the sixth transistor are n-channel field-effect transistors.

13. The display device according to claim 12, wherein
the first transistor, the second transistor, the third transistor, the fourth transistor, the fifth transistor, and the sixth transistor include an oxide semiconductor.
